(19) United States
(12) Patent Application Publication
(10) Pub. No.: US 2026/0250500 A1
(43) Pub. Date: Aug. 27, 2026

(54) THERMOSETTING RESIN COMPOSITION, CURED PRODUCT, AND FLEXIBLE PRINTED BOARD

(71) Applicant: Resonac Corporation, Tokyo (JP)

(72) Inventors: Ryota MORIYAMA, Tokyo (JP); Satoshi UEHARA, Tokyo (JP); Takuya MORI, Tokyo (JP)

(21) Appl. No.: 18/862,123

(22) PCT Filed: Apr. 26, 2024
(86) PCT No.: PCT/JP2024/016484

§ 371 Date: Oct. 31, 2024

(30) Foreign Application Priority Data
Jul. 14, 2023 (JP) 2023-116179

(51) Int. Cl. C08L 33/24; H05K 1/03

(52) U.S. Cl. CPC C08L 33/24; H05K 1/0393; C08L 2203/16; C08L 2203/206

(57) ABSTRACT

An embodiment relates to a thermosetting resin composition including a resin having at least one group selected from the group consisting of an acid anhydride group and a carboxy group, and a trifunctional amine-type epoxy resin.

### TECHNICAL FIELD

The present disclosure relates to a thermosetting resin composition, a thermosetting resin composition set, a cured product, a film, a flexible printed board, and an electronic component.

### BACKGROUND ART

Flexible printed boards are widely used in electronic devices such as various displays and smartphones. Flexible printed boards generally have protective films for ensuring electrical insulation between wiring sections, and for preventing corrosion of wiring. The protective films can be formed using thermosetting resin compositions, for example. The protective films are required to have characteristics suitable for usage applications thereof.

Patent Literature 1 discloses a thermosetting resin composition containing an (A) resin with at least one acid anhydride group and/or a carboxy group, a (B) inorganic filler containing hydrotalcite and silica, and a (C) epoxy resin, for example.

### CITATION LIST

### Patent Literature

[Patent Literature 1] JP 2009-275114 A

### SUMMARY OF THE INVENTION

### Problems to be Solved by the Invention

Dirt may adhere to surfaces of electronic devices such as television (TV) panels and personal computer (PC) displays depending on use environments, and end users may use detergents to remove the dirt. Detergents may accidentally permeate into the interior of the displays and reach flexible printed boards, and cause short circuits between wiring sections, if functionality of protecting wiring by protective films is not sufficient.

Therefore, the present disclosure provides a thermosetting resin composition that can be used for forming a flexible printed board, and an electronic component having excellent resistance to detergents. Further, the present disclosure provides a thermosetting resin composition set for obtaining the thermosetting resin composition, which includes a first agent and a second agent, and a cured product and a film obtained using the thermosetting resin composition or the thermosetting resin composition set. Still further, the present disclosure provides a flexible printed board and an electronic component having excellent resistance to detergents.

### Means for Solving the Problem

Embodiments of the present invention will be described below. However, the present invention is not limited to the following embodiments.

One embodiment relates to a thermosetting resin composition including: a resin having at least one group selected from the group consisting of an acid anhydride group and a carboxy group; and a trifunctional amine-type epoxy resin.

Another embodiment relates to a thermosetting resin composition set for obtaining the thermosetting resin composition, the thermosetting resin composition set including: a first agent containing the resin; and a second agent containing the trifunctional amine-type epoxy resin.

Another embodiment relates to a cured product obtained using the thermosetting resin composition, or the thermosetting resin composition set.

Another embodiment relates to a film obtained using the thermosetting resin composition, or the thermosetting resin composition set.

Another embodiment relates to a flexible printed board obtained using the thermosetting resin composition, or the thermosetting resin composition set.

Another embodiment relates to an electronic component obtained using the thermosetting resin composition, or the thermosetting resin composition set.

### Advantageous Effect of the Invention

According to the present disclosure, it is possible to provide a thermosetting resin composition that can be used for forming a flexible printed board and an electronic component having excellent resistance to detergents. Further, according to the present disclosure, it is possible to provide a thermosetting resin composition set for obtaining the thermosetting resin composition, which includes a first agent and a second agent, and a cured product and a film obtained using the thermosetting resin composition or the thermosetting resin composition set. Still further, according to the present disclosure, it is possible to provide a flexible printed board and an electronic component having excellent resistance to detergents.

### BRIEF DESCRIPTION OF THE DRAWINGS

FIG. 1 is a schematic front view illustrating a test piece for evaluating detergent resistance prepared in examples.

FIG. 2 is a schematic front view illustrating an enlarged wiring portion of the test piece illustrated in FIG. 1.

FIG. 3 is a schematic front view illustrating a state in which a test piece is in contact with a detergent in examples.

FIG. 4 is a schematic perspective view illustrating a state in which a test piece is in contact with a detergent in examples.

### MODES FOR CARRYING OUT THE INVENTION

Embodiments of the present invention will be described. The present invention is not limited to the following embodiments. Further, one of the following embodiments may be implemented alone, or a combination of the embodiments may be implemented. Combinations of a plurality of embodiments are also included in the present invention.

In numerical ranges described in a stepwise manner in the present disclosure, an upper or lower limit of a certain numerical range may be replaced with an upper or lower limit of another numerical range. Upper or lower limits of numerical ranges described in the present disclosure may be replaced with values in examples. Certain numerical values may be selected from both upper limit numerical values and lower limit numerical values described in a stepwise manner in the present disclosure to form stepwise numerical ranges. Upper and lower limit numerical values described in the present disclosure may be replaced with values in examples.

In the present disclosure, each component may contain a plurality types of substances corresponding to each component. If a composition has a plurality types of substances corresponding to each component, a content ratio or amount of each component means a content ratio or amount of a total of the plurality types of substances present in the composition, unless otherwise specified.

In the present disclosure, each structure of a resin or a polymer may have a plurality types of structures corresponding to each structure. If a resin or a polymer has a plurality types of structures corresponding to each structure, a content ratio or amount of each structure means a content ratio or amount of a total of the plurality types of structures present in the resin or the polymer, unless otherwise specified.

In the present disclosure, a “layer” includes a continuous layer and a discontinuous layer. The thickness of the “layer” may be uniform or non-uniform. A planar outer edge and an outer edge in a thickness direction of the “layer” may be clearly defined or unclearly defined. The same applies to a “film”.

When embodiments are described in the present disclosure with reference to the drawings, configurations of the embodiments are not limited to configurations illustrated in the drawings. Further, sizes of members in each drawing are conceptual, and the relative relationship of sizes between members is not limited to the relationship illustrated in the drawings.

### <Thermosetting Resin Composition>

In one or more embodiments, a thermosetting resin composition contains a resin having at least one group selected from the group consisting of an acid anhydride group and a carboxy group; and a trifunctional amine-type epoxy resin. In the present disclosure, a resin having at least one group selected from the group consisting of an acid anhydride group and a carboxy group may be referred to as “resin A”. At least one group selected from the group consisting of an acid anhydride group and a carboxy group may be referred to as “an acid anhydride group or a carboxy group”. In the present disclosure, an acid anhydride group may be a carboxylic acid anhydride group. The thermosetting resin composition may further contain a tetrafunctional amine-type epoxy resin, an epoxy resin other than an amine-type epoxy resin, an organic solvent, and an optional component such as an additive.

### [Resin Having Acid Anhydride Group or Carboxy Group]

An example of a resin having an acid anhydride group or a carboxy group includes a resin having an acid anhydride group or a carboxy group in a main chain, a side chain, or both a main chain and a side chain, such as a phenolic resin, an acrylic resin, a polyurethane, a polybutadiene, a hydrogenated polybutadiene, a polyester, a polycarbonate, a polyether, a polysulfone, a polytetrafluororesin, a polysilicone, a melamine resin, a polyamide, a polyamideimide, or a polyimide. The thermosetting resin composition may contain a single type of resin having an acid anhydride group or a carboxy group alone, or two or more types in combination.

In one or more embodiments, the thermosetting resin composition contains a polyamideimide having an acid anhydride group or a carboxy group. A polyamideimide is a resin that includes an amide bond (amide group) and an imide bond (imide group). When the thermosetting resin composition contains the polyamideimide having an acid anhydride group or a carboxy group, it is possible to obtain a cured product having excellent insulation and heat resistance, and excellent resistance to detergents. In the present disclosure, resistance to detergents may be referred to as “detergent resistance”. The polyamideimide may have an acid anhydride group or a carboxy group at a terminal of the molecular chain.

In one or more embodiments, the polyamideimide may include a urethane bond. The polyamideimide including a urethane bond can be synthesized by performing a method for reacting a polyol with a polyisocyanate to obtain a polyisocyanate having a urethane bond (in the present disclosure, the polyisocyanate may be referred to as “polyisocyanate A”), and reacting the polyisocyanate with a tricarboxylic acid compound, for example. The polyamideimide may have a polyurethane structure within the molecule from the viewpoint of enhancing flexibility. The polyol may be used alone, or in combination of two or more. The polyisocyanate may be used alone, or in combination of two or more.

### (Polyol)

An example of a polyol includes a diol such as an alicyclic diol, an aliphatic diol, or a diol compound represented by formula (P1) below. The diol may contain an alicyclic diol from the viewpoint of obtaining a cured product having excellent bending ability, while maintaining high insulation reliability. The diol may contain an aliphatic diol from the viewpoint of obtaining a cured product having excellent flexibility, while sufficiently suppressing warpage thereof. In the present disclosure, a property of suppressing warpage may be referred to as “low warpage”.

The alicyclic diol is a diol having a divalent organic group having an alicyclic hydrocarbon group. The number of carbon atoms of the alicyclic hydrocarbon group is 5 to 10, for example. Examples of the alicyclic diol include five-membered ring diols such as 1,2-cyclopentanedimethanol, 1,3-cyclopentanedimethanol, and bis(hydroxymethyl)tricyclo[5.2.1.0]decane; and six-membered ring diols such as 1,2-cyclohexanediol, 1,3-cyclohexanediol, 1,4-cyclohexanediol, 1,2-cyclohexanedimethanol, 1,3-cyclohexanedimethanol, 1,4-cyclohexanedimethanol, and 2,2-bis(4-hydroxycyclohexyl)-propane.

The aliphatic diol is a diol that includes a divalent organic group having an aliphatic hydrocarbon group (however, the divalent organic group does not have an alicyclic hydrocarbon group). The number of carbon atoms of the aliphatic hydrocarbon group is 1 to 18, for example. The aliphatic hydrocarbon group may be linear or branched. Examples of the aliphatic diol include ethylene glycol, propylene glycol, diethylene glycol, 1,4-butanediol, neopentyl glycol, and 1,6-hexane glycol.

The diol may be the diol compound represented by the following formula (P1), for example.

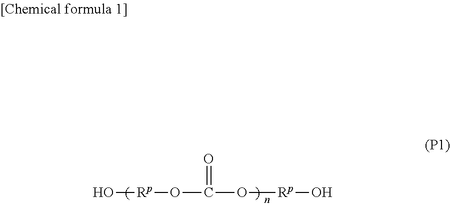

In the formula, R^{p} represents a divalent organic group having an alicyclic hydrocarbon group of 5 to 10 carbon atoms, or a divalent organic group having an aliphatic hydrocarbon group of 1 to 18 carbon atoms, the divalent organic group does not have an alicyclic hydrocarbon group, and n represents a number from 1 to 30. R^{p}s may be the same or different from each other. The divalent organic group having an aliphatic hydrocarbon group is a linear or branched alkylene group, for example. n is the average number of units.

The diol compound represented by formula (P1) may be a copolymerized carbonate diol including a structure derived from a diol including a divalent organic group having an alicyclic hydrocarbon group as R^{p}, and a structure derived from a diol including a divalent organic group having an aliphatic hydrocarbon group as R^{p}, for example.

In the copolymerized carbonate diol, a molar ratio of the structure derived from a diol including a divalent organic group having an aliphatic hydrocarbon group, to the structure derived from a diol including a divalent organic group having an alicyclic hydrocarbon group, is 0.1 or more, 0.3 or more, or 0.5 or more, from the viewpoint of obtaining excellent insulation reliability and folding endurance, for example. From the same viewpoint, the molar ratio is 2 or less, 1 or less, or 0.5 or less, for example. The molar ratio is in a range from 0.1 to 2, in a range from 0.3 to 1, in a range from 0.1 to 0.5, or in a range from 0.5 to 1, for example. n is in a range from 10 to 30, in a range from 15 to 28, or in a range from 20 to 25, for example.

The diol including a divalent organic group having an alicyclic hydrocarbon group may be 1,4-cyclohexanedimethanol, and the diol including a divalent organic group having an aliphatic hydrocarbon group may be 1,6-hexanediol, for example. In other words, the diol compound represented by formula (P1) may be a copolymerized carbonate diol, which is a copolymer using 1,4-cyclohexanedimethanol and 1,6-hexanediol. A copolymerized carbonate diol in which a molar ratio between 1,4-cyclohexanedimethanol and 1,6-hexanediol is 3/1 is commercially available as “UM-90 (3/1)” manufactured by UBE Corporation. A copolymerized carbonate diol in which a molar ratio between 1,4-cyclohexanedimethanol and 1,6-hexanediol is 1/1 is commercially available as “UM-90 (1/1)” manufactured by UBE Corporation. A copolymerized carbonate diol in which a molar ratio between 1,4-cyclohexanedimethanol and 1,6-hexanediol is ⅓ is commercially available as “UM-90 (⅓)” manufactured by UBE Corporation.

The diol compound represented by formula (P1) may be a carbonate diol in which R^{p} includes a structure derived from a diol including a divalent organic group having an aliphatic hydrocarbon group, for example. In the carbonate diol, n is, in a range from 2 to 10, in a range from 3 to 8, or in a range from 4 to 6, for example.

The diol including a divalent organic group having an aliphatic hydrocarbon group may be 1,6-hexanediol, for example. In other words, the diol compound represented by formula (P1) may be a carbonate diol, which is a polymer using 1,6-hexanediol. Examples of the diol compound represented by formula (P1), in which R^{p} represents a divalent organic group having an aliphatic hydrocarbon group, include α,ω-poly(hexamethylene carbonate)diol and α,ω-poly(3-methyl-pentamethylene carbonate)diol. Examples of commercially available products thereof include PLACCEL CD-205, 205 PL, 205 HL, 210, 210 PL, 210 HL, 220, 220 PL, 220 HL manufactured by Daicel Corporation; PCDL T-5651, T-5652, T-6001, T-6002, G-3452, PCDX-55 manufactured by Asahi Kasei Corp.; and UH-50, 100, 200, 300, UHC-50-100, 200 manufactured by UBE Corporation.

The number average molecular weight of the diol compound represented by formula (P1) is 300 or more, 500 or more, or 700 or more, for example. The number average molecular weight is 4,000 or less, 3,000 or less, or 2,000 or less, for example. The number average molecular weight is in a range from 300 to 4,000, in a range from 500 to 3,000, or in a range from 700 to 2,000, for example. In the present disclosure, the number average molecular weight refers to a value obtained through the measurement by gel permeation chromatography (GPC) and the conversion with the use of a calibration curve of standard polystyrene. Examples show details of a method for measuring the number average molecular weight.

In the polyamideimide, the molar ratio of the structure derived from a diol including a divalent organic group having an aliphatic hydrocarbon group, to the structure derived from a diol including a divalent organic group having an alicyclic hydrocarbon group, is 0.1 or more, 0.3 or more, or 0.4 or more, from the viewpoint of obtaining excellent insulation reliability and folding endurance, for example. From the same viewpoint, the molar ratio is 2 or less, 1 or less, or 0.6 or less, for example. The molar ratio is in a range from 0.1 to 2, in a range from 0.3 to 1, or in a range from 0.4 to 0.6, for example.

From the viewpoint that properties such as an increase in glass transition temperature and enhancement of elastic modulus can be easily imparted, and excellent insulation reliability can be obtained, the ratio of the structure derived from an alicyclic diol, relative to the mass of the polyamideimide, may be 0.1% by mass or more, 3% by mass or more, or 5% by mass or more, for example. From the viewpoint that an increase in the crystallinity of the polyamideimide is suppressed, and favorable solubility in a solvent is easily obtained, the ratio of the structure derived from an alicyclic diol, relative to the mass of the polyamideimide, may be 30% by mass or less, 25% by mass or less, or 20% by mass or less, for example. The ratio of the structure derived from an alicyclic diol, relative to the mass of the polyamideimide, may be in a range from 0.1% by mass to 30% by mass, in a range from 3% by mass to 25% by mass, or in a range from 5% by mass to 20% by mass, for example. In the calculation of the ratio, “structure derived from an alicyclic diol” means a portion obtained by removing two hydroxy groups from the alicyclic diol. When the alicyclic diol is 1,4-cyclohexanedimethanol, a portion obtained by removing two hydroxy groups from the 1,4-cyclohexanedimethanol is regarded as the “structure derived from an alicyclic diol” to calculate the ratio.

The diol may be a polyether diol, a polyester diol, a polycaprolactone diol, a silicone diol, or the like, for example.

As the polyol, a triol having three hydroxy groups may be used in combination with a diol. Examples of the triol include 1,2,3-propanetriol (glycerin), 1,2,4-butanetriol, and the like.

### (Polyisocyanate)

An example of a polyisocyanate includes a diisocyanate compound represented by the following formula (P3).

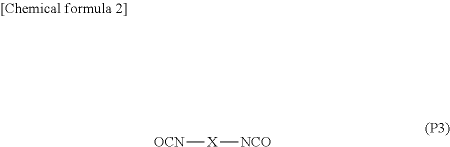

In the formula, X represents a divalent organic group.

Examples of the divalent organic group represented by X in formula (P3) include an alkylene group of 1 to 20 carbon atoms; an arylene group such as a phenylene group or a naphthylene group, which is unsubstituted or substituted with a lower alkyl group of 1 to 5 carbon atoms, such as a methyl group, or a lower alkoxy group of 1 to 5 carbon atoms, such as a methoxy group; an organic group in which two arylene groups above are bonded via a lower alkylene group of 1 to 5 carbon atoms, an oxy group (—O—), a carbonyl group (—CO—), or a sulfonyl group (—SO₂—); and an organic group in which two lower alkylene groups, each having 1 to 5 carbon atoms, are bonded via the arylene group above. The number of carbon atoms of the alkylene group may be 1 to 18, for example. The divalent organic group represented by X is selected from groups having an aromatic ring such as a phenylene group, a xylylene group, a naphthylene group, a diphenylmethane-4,4′-diyl group, and a diphenylsulfone-4,4′-diyl group, and hydrogenated groups thereof.

Examples of the diisocyanate compound represented by formula (P3) include aromatic isocyanates such as diphenylmethane diisocyanate compounds such as diphenylmethane-2,4′-diisocyanate, “3,2′-, 3,3′-, 4,2′-, 4,3′-, 5,2′-, 5,3′-, 6,2′-, or 6,3′-dimethyldiphenylmethane-2,4′-diisocyanate”, “3,2′-, 3,3′-, 4,2′-, 4,3′-, 5,2′-, 5,3′-, 6,2′-, or 6,3′-diethyldiphenylmethane-2,4′-diisocyanate”, “3,2′-, 3,3′-, 4,2′-, 4,3′-, 5,2′-, 5,3′-, 6,2′-, or 6,3′-dimethoxydiphenylmethane-2,4′-diisocyanate”, diphenylmethane-4,4′-diisocyanate, diphenylmethane-3,3′-diisocyanate, and diphenylmethane-3,4′-diisocyanate; diphenyl ether-4,4′-diisocyanate; benzophenone-4,4′-diisocyanate; diphenylsulfone-4,4′-diisocyanate; tolylene-2,4-diisocyanate (2,4-tolylene diisocyanate); tolylene-2,6-diisocyanate (2,6-tolylene diisocyanate); m-xylylene diisocyanate; p-xylylene diisocyanate; 1,5-naphthalene diisocyanate; and 4,4′-[2,2-bis(4-phenoxyphenyl)propane]diisocyanate.

Examples of the diisocyanate compound represented by formula (P3) include aliphatic or alicyclic isocyanates such as hexamethylene diisocyanate, 2,2,4-trimethylhexamethylene diisocyanate, isophorone diisocyanate, 4,4′-dicyclohexylmethane diisocyanate, transcyclohexane-1,4-diisocyanate, lysine diisocyanate, and hydrogenated products of an aromatic isocyanate.

An isocyanate group included in the diisocyanate compound represented by formula (P3) may be stabilized with a blocking agent to avoid changes over time. Examples of the blocking agent include, but not particularly limited to, alcohols typified by a hydroxy acrylate and methanol; phenol; and oxime.

As the polyisocyanate, a trifunctional or greater polyisocyanate may be used together with the diisocyanate compound represented by formula (P3).

### (Reaction Method and the Like)

The reaction between the polyol and the polyisocyanate can be performed by heating and condensing these compounds in the presence of an organic solvent, for example, a polar solvent containing no nitrogen. The organic solvent may be used alone, or in combination of two or more.

The polar solvent containing no nitrogen is selected from ether-based solvents such as diethylene glycol dimethyl ether, diethylene glycol diethyl ether, triethylene glycol dimethyl ether, and triethylene glycol diethyl ether; sulfur-containing solvents such as dimethyl sulfoxide, diethyl sulfoxide, dimethyl sulfone, and sulfolane; ester-based solvents such as γ-butyrolactone and cellosolve acetate; ketone-based solvents such as cyclohexanone and methylethylketone; and aromatic hydrocarbon-based solvents such as toluene and xylene, for example.

It is possible to select and use a solvent in which a resin produced can be dissolved. It is possible to select and use a solvent which can be used as it is as a solvent for the thermosetting resin composition after synthesis. The solvent may be γ-butyrolactone from the viewpoint that γ-butyrolactone has a high boiling point, can efficiently perform the reaction in a homogeneous system, and is suitable for printing work when a protective film is formed on a flexible wiring board or the like.

From the viewpoint that an increase in viscosity during the reaction is suppressed, and synthesis of the polyisocyanate A is performed favorably, the amount used of the solvent is 0.8 times (mass ratio) or more, relative to the total mass of raw materials used for the synthesis of the polyisocyanate A, for example. From the viewpoint of suppressing a decrease in a reaction rate, the amount used of the solvent is 5.0 times (mass ratio) or less, for example.

From the viewpoint of suppressing reaction time from being long, a reaction temperature is 70° C. or higher, 75° C. or higher, or 80° C. or higher, for example. From the viewpoint of preventing gelation during the reaction, the reaction temperature is 210° C. or lower, 190° C. or lower, or 180° C. or lower, for example. The reaction time can be appropriately selected depending on the content of a reaction container, reaction conditions adopted, and the like.

If necessary, the reaction may be performed in the presence of catalysts such as tertiary amines, alkali metals, alkaline earth metals, metals such as tin, zinc, titanium, and cobalt, or metalloid compounds.

The blending ratio when the polyol is reacted with the polyisocyanate may be appropriately adjusted by taking into account the number average molecular weight of the polyisocyanate A to be produced, and the polyisocyanate A to be produced having an isocyanate group at a terminal thereof, for example.

In order to synthesize the polyisocyanate A having an isocyanate group at a terminal thereof, the blending ratio of the polyol and the polyisocyanate can be adjusted such that the ratio between the number of isocyanate groups and the number of hydroxy groups (the number of isocyanate groups/the number of hydroxy groups) is 1.01 or more and 2.0 or less, for example.

The polyisocyanate A is a compound having a urethane bond, and includes a structure represented by formula (P2) below, for example.

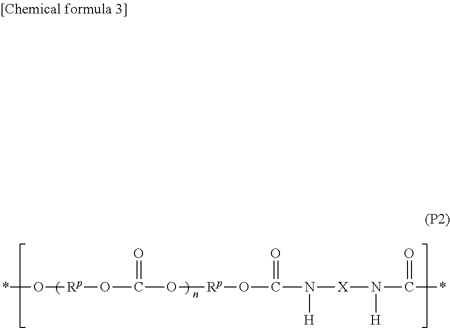

In the formula, R^{p} represents a divalent organic group having an alicyclic hydrocarbon group of 5 to 10 carbon atoms, or a divalent organic group having an aliphatic hydrocarbon group of 1 to 18 carbon atoms, the divalent organic group does not have an alicyclic hydrocarbon group, X represents a divalent organic group, and n represents a number from 1 to 30. R^{p}s may be the same or different from each other. The symbol * represents a bonding site to another structure. The description of R^{p} and X in formula (P1) can be applied for R^{p} and X in formula (P2).

The number average molecular weight of the polyisocyanate A is 500 or more, 1,000 or more, or 1,500 or more, for example. The number average molecular weight of the polyisocyanate A is 30,000 or less, 25,000 or less, or 20,000 or less, for example. The number average molecular weight of the polyisocyanate A is in a range from 500 to 30,000, in a range from 1,000 to 25,000, or in a range from 1,500 to 20,000, for example.

### (Tricarboxylic Acid Compound)

The tricarboxylic acid compound may be a trivalent polycarboxylic acid having an acid anhydride group, and a derivative thereof. The derivative is an ester, for example. An example of the tricarboxylic acid compound includes a compound represented by formula (P4) or (P5) below.

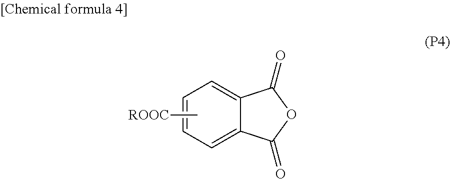

In formula (P4), R represents a hydrogen atom, an alkyl group of 1 to 10 carbon atoms, or a phenyl group.

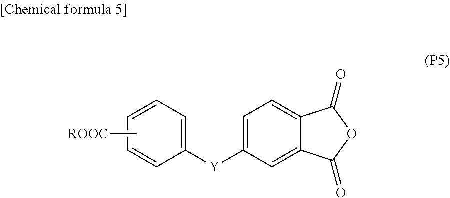

In formula (P5), R represents a hydrogen atom, an alkyl group of 1 to 10 carbon atoms, or a phenyl group, and Y represents —CH₂—, —CO—, —SO₂—, or —O—.

A specific example of the tricarboxylic acid compound includes a trimellitic acid anhydride, benzenetricarboxylic acid anhydride, naphthalenetricarboxylic acid anhydride, 3,4,4′-benzophenonetricarboxylic acid anhydride, 3,4,4′-biphenyl ether tricarboxylic acid anhydride, 3,4,4′-biphenyl tricarboxylic acid anhydride, 2,3,2′-biphenyl tricarboxylic acid anhydride, 3,4,4′-biphenyl methane tricarboxylic acid anhydride, or 3,4,4′-biphenyl sulfone tricarboxylic acid anhydride.

A dicarboxylic acid compound which is a divalent polycarboxylic acid or a derivative thereof, and a tetracarboxylic acid compound which is a tetravalent polycarboxylic acid or a derivative thereof, may be used together with the tricarboxylic acid compound.

### (Reaction Method and the Like)

The organic solvent described above can be used for the reaction between the polyisocyanate A and the tricarboxylic acid compound. The solvent used for the reaction may be the same as the organic solvent used for the reaction between the polyol and the polyisocyanate.

From the viewpoint of suppressing an increase in viscosity during the solvent reaction, and performing synthesis of the polyamideimide favorably, the amount used of the solvent is 0.8 times (mass ratio) or more, relative to the total mass of raw materials used for the synthesis of the polyamideimide, for example. From the viewpoint of suppressing a decrease in the reaction rate, the amount used of the solvent is 5.0 times (mass ratio) or less, for example.

From the viewpoint of suppressing the reaction time from being long, a reaction temperature is 70° C. or higher, 75° C. or higher, or 80° C. or higher, for example. From the viewpoint of preventing gelation during the reaction, the reaction temperature is 210° C. or lower, 190° C. or lower, or 180° C. or lower, for example. The reaction time can be appropriately selected depending on the content of a reaction container, reaction conditions adopted, and the like.

The polyisocyanate A may be reacted with the tricarboxylic acid compound, together with a polyisocyanate other than the polyisocyanate A (in the present disclosure, the polyisocyanate may be referred to as “polyisocyanate B”), to obtain a polyamideimide. There are no particular limitations on the polyisocyanate B, as long as the polyisocyanate B is an isocyanate other than the polyisocyanate A. Examples of the polyisocyanate B include the diisocyanate compound represented by formula (P3), a trivalent or higher polyisocyanate, and the like. The polyisocyanate A and the polyisocyanate B, each independently, may be used alone or in combination of two or more.

When the polyisocyanate B is used in combination, the polyisocyanate B may include an aromatic polyisocyanate in a range from 50% by mass to 100% by mass, relative to the total mass of the polyisocyanate B. The aromatic polyisocyanate contains at least one selected from 4,4′-diphenylmethane diisocyanate and tolylene diisocyanate, from the viewpoint of balance of solubility, mechanical characteristics, and cost, for example.

When the polyisocyanate B is used in combination, the molar ratio of the polyisocyanate A/polyisocyanate B is in a range from 0.1/0.9 to 0.9/0.1, in a range from 0.2/0.8 to 0.8/0.2, or in a range from 0.3/0.7 to 0.7/0.3, for example. The molar ratio being in the above range can easily achieve favorable adhesion between a cured product, and an object to which the cured product is to be attached such as a substrate with wiring.

An amine compound can also be used together with the polyisocyanate A. An example of the amine compound includes a compound obtained by converting the isocyanate groups in the diisocyanate compound represented by formula (P3) to amino groups. The conversion of the isocyanate groups to the amino groups can be performed by means of a known method.

In the reaction between the polyisocyanate A and the tricarboxylic acid compound, from the viewpoint of increasing the number average molecular weight of the polyamideimide, the ratio of the total number of acid anhydride groups and carboxy groups in the acid anhydride and carboxylic acid used, to the total number of isocyanate groups in the isocyanate used (the total number of acid anhydride groups and carboxy groups/the total number of isocyanate groups), is 0.6 or more, 0.7 or more, or 0.8 or more, for example. From the same viewpoint, the ratio of the total number of carboxy groups and acid anhydride groups is 1.4 or less, 1.3 or less, or 1.2 or less, for example. The ratio of the total number of carboxy groups and acid anhydride groups is in a range from 0.6 to 1.4, in a range from 0.7 to 1.3, or in a range from 0.8 to 1.2, for example.

From the viewpoint of preventing deterioration in weather resistance or detergent resistance, the number average molecular weight of the polyamideimide is 5,000 or more, 6,000 or more, or 7,000 or more, for example. From the viewpoint of being favorably dissolved in a solvent, and not becoming insoluble during synthesis, the number average molecular weight is 65,000 or less, 60,000 or less, 50,000 or less, or 25,000 or less, for example. The number average molecular weight of the polyamideimide is in a range from 5,000 to 60,000, in a range from 6,000 to 50,000, or in a range from 7,000 to 25,000, for example.

From the viewpoint of preventing deterioration in weather resistance or solvent resistance, the weight average molecular weight of the polyamideimide is 10,000 or more, 20,000 or more, or 30,000 or more, for example. From the viewpoint of being favorably dissolved in a solvent, and not becoming insoluble during synthesis, the number average molecular weight is 65,000 or less, 60,000 or less, or 50,000 or less, for example. The weight average molecular weight of the polyamideimide is in a range from 10,000 to 65,000, in a range from 20,000 to 60,000, or in a range from 30,000 to 50,000, for example.

In the present disclosure, the number average molecular weight and the weight average molecular weight refer to values obtained through measurement by gel permeation chromatography (GPC), and conversion with the use of a calibration curve of standard polystyrene. Examples show details of methods of measuring the number average molecular weight and the weight average molecular weight.

From the viewpoint of obtaining sufficient curing properties, favorable weather resistance, bending resistance, and the like, an acid value of the polyamideimide is 5 mgKOH/g or more, 7 mgKOH/g or more, or 10 mgKOH/g or more, for example. From the viewpoint of obtaining favorable low warpage, thermosetting properties, and insulation reliability, the acid value of the polyamideimide is 30 mgKOH/g or less, 20 mgKOH/g or less, or 15 mgKOH/g or less, for example. The acid value of the polyamideimide is in a range from 5 mgKOH/g to 30 mgKOH/g, in a range from 7 mgKOH/g to 20 mgKOH/g, or in a range from 10 mgKOH/g to 15 mgKOH/g, for example. The acid value can be measured by means of a neutralization titration method. Examples show details of a method for measuring the acid value.

The polyamideimide obtained by performing the above production method can have a carboxy group or an acid anhydride group at a terminal of the molecular chain, for example. When the polyamideimide has a urethane bond and has a carboxy group or an acid anhydride group at a terminal of the molecular chain, flexibility and insulation reliability can be enhanced.

The resin A contained in the thermosetting resin composition is not limited to a polyamideimide having an acid anhydride group or a carboxy group. In one or more embodiments, the thermosetting resin composition contains polyurethane having an acid anhydride group or a carboxy group. From the viewpoint of enhancing flexibility, the polyurethane may have an ester bond within the molecule. The polyurethane may have a fluorene structure; or may have a cardo structure. In one or more embodiments, the thermosetting resin composition contains polyimide having an acid anhydride group or a carboxy group. From the viewpoint of enhancing flexibility, the polyimide may have a carbonate structure within the molecule. The polyimide may have a fluorene structure; or may have a cardo structure.

### [Epoxy Resin]

The thermosetting resin composition contains a trifunctional amine-type epoxy resin. The thermosetting resin composition may further contain a tetrafunctional amine-type epoxy resin. The thermosetting resin composition may further contain an epoxy resin other than an amine-type epoxy resin (in the present disclosure, the epoxy resin other than an amine-type epoxy resin may be referred to as a “non-amine type epoxy resin”). In the present disclosure, the trifunctional amine-type epoxy resin is a compound that has a secondary amine structure, a tertiary amine structure, or both structures, and has three epoxy groups within the molecule. The tetrafunctional amine-type epoxy resin is a compound that has a secondary amine structure, a tertiary amine structure, or both structures, and has four epoxy groups within the molecule. The non-amine type epoxy resin is a compound that has neither a secondary amine structure nor a tertiary amine structure, and has one or more epoxy groups within the molecule. The trifunctional amine-type epoxy resin, the tetrafunctional amine-type epoxy resin, and the non-amine type epoxy resin, each independently, may be contained alone or in combination of two or more in the thermosetting resin composition.

### (Trifunctional Amine-Type Epoxy Resin)

The trifunctional amine-type epoxy resin may have a monoglycidyl amino group, a diglycidyl amino group, or both groups, for example. The trifunctional amine-type epoxy resin may further have a glycidyloxy group. The trifunctional amine-type epoxy resin includes an epoxy resin represented by formula (E1), for example.

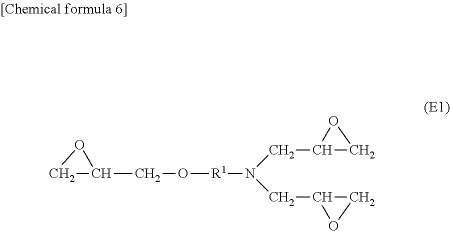

(In the formula, R¹ represents a divalent organic group.)

Examples of R¹ include the groups exemplified in the description of X in the diisocyanate compound represented by formula (P3) described above. R¹ may represent an arylene group such as a phenylene group or a naphthylene group, which is unsubstituted or substituted with a lower alkyl group of 1 to 5 carbon atoms, such as a methyl group, or a lower alkoxy group of 1 to 5 carbon atoms, such as a methoxy group; may represent a phenylene group which is unsubstituted or substituted with a lower alkyl group of 1 to 5 carbon atoms, such as a methyl group; or may represent an unsubstituted phenylene group or a methylphenylene group.

When the thermosetting resin composition contains a trifunctional amine-type epoxy resin, it is possible to obtain a flexible printed board and an electronic component having excellent detergent resistance. The reason thereof is assumed as follows, for example. However, the present invention is not limited by the following.

When the thermosetting resin composition contains a trifunctional amine-type epoxy resin, adhesion between a cured product such as a protective film, and an object to be protected such as a substrate with wiring is enhanced. In particular, when the object to be protected includes a film having an imide bond, an amide bond, or both an imide bond and an amide bond, such as a polyimide film, a polyamideimide film, or a polyamide film, intermolecular interaction between the amine structure, and the imide bond or the amide bond in the film, which are similar sites having high polarity, is increased, and adhesion is further enhanced. Further, when the thermosetting resin composition contains a trifunctional amine-type epoxy resin, there is a tendency to be able to obtain a film in which the occurrence of warpage is suppressed. The larger the number of epoxy groups within the molecule of an epoxy resin, the denser the cured product becomes with the epoxy resin as a crosslinking point, and warpage is likely to occur in the cured product such as a protective film. The smaller the number of epoxy groups within the molecule of an epoxy resin, the less dense the cured product becomes, and it is considered that shrinkage is suppressed, and warpage of the cured product is reduced. Meanwhile, when the amine-type epoxy resin has two or less functional groups, it is not possible to introduce a network structure caused by the epoxy resin into the cured product. With the trifunctional amine-type epoxy resin, the network structure can be introduced into the cured product, and it is possible to prevent the resin from becoming dense.

For these reasons, it is considered that the permeation of a detergent into an interface between the cured product and the object to be protected is suppressed, and short circuits between wiring sections caused by a detergent, and short circuits caused by migration due to metal precipitation, can be prevented.

The epoxy equivalent of the trifunctional amine-type epoxy resin is in a range from 70 g/eq to 120 g/eq, in a range from 80 g/eq to 115 g/eq, or in a range from 90 g/eq to 110 g/eq, for example. When the epoxy equivalent is 120 g/eq or less, the number of epoxy groups per mass becomes sufficient, and the adhesion to the object to be protected tends to be enhanced. In particular, when the trifunctional amine-type epoxy resin has a monoglycidyl amino group, a diglycidyl amino group, or both groups, it is easy to obtain an effect of enhancing the adhesion due to the amine structure. When the epoxy equivalent is 70 g/eq or more, crosslinking points tend to be prevented from becoming dense. The epoxy equivalent can be measured according to JIS K7236:2001, for example.

Examples of commercially available products of the trifunctional amine-type epoxy resin include “EP-3950E”, “EP-3950S”, and “EP-3950L” manufactured by ADEKA CORPORATION; “SUMI-EPOXY ELM-100” and “SUMI-EPOXY ELM-100H” manufactured by SUMITOMO CHEMICAL COMPANY, LIMITED; and “jER630” and “jER630LSD” manufactured by Mitsubishi Chemical Corporation.

The content ratio of the trifunctional amine-type epoxy resin is in a range from 1% by mass to 16% by mass, in a range from 2% by mass to 14% by mass, in a range from 3% by mass to 12% by mass, or in a range from 3% by mass to 10% by mass, relative to the mass of the resin A, for example. When the content ratio is within the above range, more favorable detergent resistance is easily obtained. In particular, from the viewpoint of obtaining excellent detergent resistance, the content ratio of the trifunctional amine-type epoxy resin may be in a range from 5% by mass to 16% by mass, in a range from 7% by mass to 12% by mass, or in a range from 8% by mass to 10% by mass.

### (Tetrafunctional Amine-Type Epoxy Resin)

The tetrafunctional amine-type epoxy resin may have a monoglycidyl amino group, a diglycidyl amino group, or both groups, for example. Further, the tetrafunctional amine-type epoxy resin may have a glycidyloxy group. The tetrafunctional amine-type epoxy resin includes an epoxy resin represented by formula (E2) below, for example.

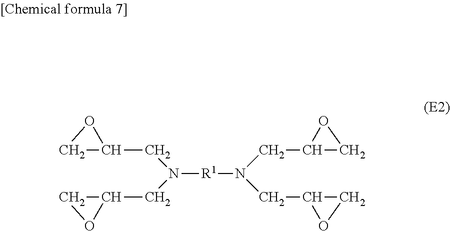

### (In the Formula, R² Represents a Divalent Organic Group.)

Examples of R² include the groups exemplified in the description of X of the diisocyanate compound represented by formula (P3) above. R² may represent an alkylene group of 1 to 20 carbon atoms; an arylene group such as a phenylene group or a naphthylene group, which is unsubstituted or substituted with a lower alkyl group of 1 to 5 carbon atoms, such as a methyl group, or a lower alkoxy group of 1 to 5 carbon atoms, such as a methoxy group; or may represent an organic group in which two arylene groups above are bonded via a lower alkylene group of 1 to 5 carbon atoms, an oxy group (—O—), a carbonyl group (—CO—), or a sulfonyl group (—SO₂—). The alkylene group of 1 to 20 carbon atoms may be a linear, branched, or cyclic alkylene group; may be a cyclic alkylene group; or may be a cyclohexylene group. The arylene group may be an unsubstituted arylene group; or may be an unsubstituted phenylene group. The organic group may be an organic group in which two phenylene groups are bonded via a lower alkylene group of 1 to 5 carbon atoms; or may be a diphenylmethanediyl group (*-Ph-CH₂-Ph-* (Ph is a phenylene group)).

The epoxy equivalent of the tetrafunctional amine-type epoxy resin is in a range from 90 g/eq to 140 g/eq, in a range from 100 g/eq to 135 g/eq, or in a range from 110 g/eq to 130 g/eq, for example. When the epoxy equivalent is 140 g/eq or less, the number of epoxy groups per mass becomes sufficient, and the adhesion to the object to be protected tends to be enhanced. In particular, when the tetrafunctional amine-type epoxy resin has a monoglycidyl amino group, a diglycidyl amino group, or both groups, it is easy to obtain an effect of enhancing the adhesion due to the amine structure. When the epoxy equivalent is 90 g/eq or more, crosslinking points tend to be prevented from becoming dense.

Examples of commercially available products of the tetrafunctional amine-type epoxy resin include “YH-434” and “YH-434L” manufactured by NIPPON STEEL Chemical & Material Co., Ltd.; “SUMI-EPOXY ELM-434”, “SUMI-EPOXY ELM-434L”, and “SUMI-EPOXY ELM-434VL” manufactured by SUMITOMO CHEMICAL COMPANY, LIMITED; “jER604” manufactured by Mitsubishi Chemical Corporation; “TETRAD-X” and “TETRAD-C” manufactured by MITSUBISHI GAS CHEMICAL COMPANY, INC.; and “TG3DAS” manufactured by Konishi Chemical Ind. Co., Ltd.

When the thermosetting resin composition further contains a tetrafunctional amine-type epoxy resin, the content ratio of the tetrafunctional amine-type epoxy resin is in a range from 1% by mass to 16% by mass, in a range from 2% by mass to 10% by mass, in a range from 3% by mass to 10% by mass, or in a range from 5% by mass to 8% by mass, relative to the mass of the resin A, for example. When the content ratio is within the above range, more favorable detergent resistance is easily obtained. According to another embodiment, the thermosetting resin composition may not contain a tetrafunctional amine-type epoxy resin; or the content ratio of the tetrafunctional amine-type epoxy resin may be less than 3% by mass, less than 2% by mass, or less than 1% by mass, relative to the mass of the resin A.

When the thermosetting resin composition contains a tetrafunctional amine-type epoxy resin, the content ratio of the total of the trifunctional amine-type epoxy resin and the tetrafunctional amine-type epoxy resin is in a range from 3% by mass to 28% by mass, in a range from 4% by mass to 20% by mass, in a range from 6% by mass to 16% by mass, or in a range from 8% by mass to 10% by mass, relative to the mass of the resin A, for example.

The higher the content ratio of the trifunctional amine-type epoxy resin to the total of the trifunctional amine-type epoxy resin and the tetrafunctional amine-type epoxy resin, the better the detergent resistance may become. The content ratio of the trifunctional amine-type epoxy resin is 30% by mass or more, 50% by mass or more, 80% by mass or more, or 90% by mass or more, relative to the mass of the total of the trifunctional amine-type epoxy resin and the tetrafunctional amine-type epoxy resin, for example. The upper limit may be 100% by mass.

### (Optional Epoxy Resin)

The thermosetting resin composition may further contain an epoxy resins such as a monofunctional, difunctional, or pentafunctional or higher amine-type epoxy resin, or a non-amine type epoxy resin. Examples of the difunctional amine-type epoxy resin include “GAN” and “GOT” manufactured by Nippon Kayaku Co., Ltd.; and “EP-3980” manufactured by ADEKA CORPORATION. Examples of the non-amine type epoxy resin include a bisphenol A type epoxy resin (such as “Epikote 828” manufactured by Mitsubishi Chemical Corporation), a bisphenol F type epoxy resin (such as “YDF-170” manufactured by NIPPON STEEL Chemical & Material Co., Ltd.), a phenol novolac type epoxy resin (“Epikote 152, 154” manufactured by Mitsubishi Chemical Corporation; “EPPN-201” manufactured by Nippon Kayaku Co., Ltd.; and “DEN-438” manufactured by The Dow Chemical Company), an o-cresol novolac-type epoxy resin (“EOCN-125S, 103S, 104S” manufactured by Nippon Kayaku Co., Ltd.), a heterocycle-containing epoxy resin (such as “Araldite PT810” manufactured by BASF Japan Ltd.), an alicyclic epoxy resin (such as “ERL4234, 4299, 4221, 4206” manufactured by Union Carbide Corporation), an epoxy resin having a dicyclopentadiene skeleton (“HP-7200” and “HP-7200H” manufactured by DIC Corporation), and a polyfunctional epoxy resin (“Epon1031S” manufactured by Mitsubishi Chemical Corporation; “Araldite 0163” manufactured by BASF Japan Ltd.; “DENACOL EX-611, EX-614, EX-614B, EX-622, EX-512, EX-521, EX-421, EX-411, and EX-321” manufactured by Nagase ChemteX Corporation; “PB4700” and “EHPE3150” manufactured by Daicel Corporation; “KR470” manufactured by Shin-Etsu Chemical Co., Ltd.; “BATG” manufactured by Resonac Corporation; and “jER157S70” manufactured by Mitsubishi Chemical Corporation).

As an optional epoxy resin, the thermosetting resin composition may contain a polyfunctional epoxy resin; or may contain a trifunctional non-amine type epoxy resin or a tetrafunctional or higher non-amine type epoxy resin, for example.

When the thermosetting resin composition further contains a non-amine type epoxy resin, the content ratio of the non-amine type epoxy resin is in a range from 1% by mass to 20% by mass, or in a range from 5% by mass to 18% by mass, relative to the mass of the resin A, for example. When the content ratio is within the above range, more favorable detergent resistance is easily obtained. According to another embodiment, the thermosetting resin composition may not contain a non-amine type epoxy resin; or the content ratio may be less than 5% by mass, less than 3% by mass, or less than 1% by mass. In a cured film which is obtained from a thermosetting resin composition containing the non-amine type epoxy resin and the trifunctional amine-type epoxy resin, it is presumed that a density gradient is generated between the substrate side and the surface side in the cured film due to the difference in polarities, and the density of the trifunctional amine-type epoxy resin is higher in the substrate side.

The higher the content ratio of the trifunctional amine-type epoxy resin in the epoxy resin, the better the detergent resistance tends to be become. The content ratio of the trifunctional amine-type epoxy resin in the epoxy resin is 10% by mass or more, 30% by mass or more, 50% by mass or more, or 80% by mass or more, relative to the mass of the total epoxy resin, for example. The upper limit may be 100% by mass.

The content ratio of the total epoxy resin contained in the thermosetting resin composition is in a range from 4% by mass to 28% by mass, in a range from 5% by mass to 20% by mass, in a range from 6% by mass to 16% by mass, or in a range from 8% by mass to 10% by mass, relative to the mass of the resin A, for example. When the content ratio is within the above range, it is easy to obtain a flexible printed board and an electronic component having favorable insulation reliability, low warpage, and weather resistance. When the content ratio of the trifunctional amine-type epoxy resin in the epoxy resin is high, even if the content ratio of the total epoxy resin contained in the thermosetting resin composition is low, favorable detergent resistance tends to be obtained. As the content ratio of the total epoxy resin is low, contamination by an impurity derived from the epoxy resin into the thermosetting resin composition can be suppressed, and the insulation reliability of the flexible printed board can be enhanced. An example of an impurity derived from the epoxy resin includes chlorine caused by epichlorohydrin, which is a raw material of the epoxy resin.

The thermosetting resin composition contains the trifunctional amine-type epoxy resin in a content ratio of from 1% by mass to 16% by mass, relative to the mass of the resin A, for example. The thermosetting resin composition contains the trifunctional amine-type epoxy resin in a content ratio of from 1% by mass to 5% by mass, and the tetrafunctional amine-type epoxy resin in a content ratio of from 3% by mass to 10% by mass, relative to the mass of the resin A, for example. The thermosetting resin composition contains the trifunctional amine-type epoxy resin in a content ratio of from 1% by mass to 5% by mass, the tetrafunctional amine-type epoxy resin in a content ratio of from 3% by mass to 10% by mass, and the non-amine type epoxy resin in a content ratio of from 6% by mass to 20% by mass, relative to the mass of the resin A, for example. The non-amine type epoxy resin may be a tetrafunctional or higher epoxy resin having four or more epoxy groups.

### [Organic Solvent]

The thermosetting resin composition may further contain an organic solvent. Examples of the organic solvent include polar solvents such as N-methyl-2-pyrrolidone (NMP), N-ethyl-2-pyrrolidone (NEP), γ-butyrolactone (GBL), 3-methoxy-N,N-dimethylpropanamide (MPA), N,N′-dimethylformamide, N,N′-dimethylpropyleneurea[1,3-dimethyl-3,4,5,6-tetrahydropyrimidine-2(1H)-one], dimethyl sulfoxide, diethylene glycol dimethyl ether, triethylene glycol dimethyl ether, and sulfolane; aromatic hydrocarbon-based solvents such as xylene and toluene; and ketone-based solvents such as methylethylketone and methyl isobutyl ketone. It is preferable that the organic solvent contains at least one selected from the group consisting of N-methyl-2-pyrrolidone (NMP), N-ethyl-2-pyrrolidone (NEP), γ-butyrolactone (GBL), and 3-methoxy-N,N-dimethylpropanamide (MPA). It is more preferable that the organic solvent contains at least one selected from the group consisting of N-ethyl-2-pyrrolidone (NEP), γ-butyrolactone (GBL), and 3-methoxy-N,N-dimethylpropanamide (MPA).

As the organic solvent, the organic solvents exemplified as an organic solvent usable in the reaction between the polyol and the polyisocyanate can be used. The organic solvent may be the same organic solvent used in the reaction between the polyisocyanate A and the tricarboxylic acid compound. The organic solvent may be γ-butyrolactone, particularly from the viewpoint of printing properties such as defoaming properties and leveling properties, and suppression of outflow (bleeding) between wiring sections of the thermosetting resin composition.

The content ratio of the organic solvent can be appropriately determined depending on the usage application of the thermosetting resin composition. When application is performed by means of a screen printing method, the content ratio of the organic solvent is in a range from 20% by mass to 100% by mass, in a range from 30% by mass to 90% by mass, or in a range from 40% by mass to 80% by mass, relative to the total mass of the thermosetting resin composition, for example.

### [Optional Component]

The thermosetting resin composition may further contain a resin other than the resin having an acid anhydride group or a carboxy group; a filler; a surfactant such as an antifoaming agent or a leveling agent; a colorant such as a dye or a pigment; a thermal stabilizer, an antioxidant, a flame retardant, a lubricant, or the like, as necessary.

When the thermosetting resin composition contains a filler, at least one of a thixotropy coefficient, film formability, weather resistance of a protective film, and a printing property tends to be enhanced. Examples of the filler include an inorganic filler and an organic filler. The filler may be used alone, or in combination of two or more.

Examples of the inorganic filler include silica (SiO₂), alumina (Al₂O₃), titania (TiO₂), tantalum oxide (Ta₂O₅), zirconia (ZrO₂), silicon nitride (Si₃N₄), barium titanate (BaO·TiO₂), barium carbonate (BaCO₃), lead titanate (PbO·TiO₂), lead zirconate titanate (PZT), lead lanthanum zirconate titanate (PLZT), gallium oxide (Ga₂O₃), spinel (MgO·Al₂O₃), mullite (3Al₂O₃·2SiO₂), cordierite (2MgO·2Al₂O₃/5SiO₂), talc (3MgO·4SiO₂H₂O), aluminum titanate (TiO₂—Al₂O₃), yttria-containing zirconia (Y₂O₃—ZrO₂), barium silicate (BaO·8SiO₂), boron nitride (BN), calcium carbonate (CaCO₃), calcium sulfate (CaSO₄), zinc oxide (ZnO), magnesium titanate (MgO·TiO₂), barium sulfate (BaSO₄), carbon (C), and hydrotalcite (Mg₄Al₂(OH)₁₂CO₃·3H₂O).

From the viewpoint of heat resistance and mechanical characteristics, an example of the organic filler includes fine particles of a resin having an amide bond, an imide bond, an ester bond, or an ether bond. As the organic filler, it is possible to use a polyimide resin or a precursor thereof, a polyamideimide resin or a precursor thereof, or fine particles of a polyamide resin, for example.

The content ratio of the filler is in a range from 1% by mass to 100% by mass, in a range from 3% by mass to 50% by mass, or in a range from 5% by mass to 30% by mass, relative to the mass of the resin A, for example. When the content ratio is 1% by mass or more, tack after curing is suppressed and sticking of a film to a substrate or the like is easily prevented. When the content ratio is 100% by mass or less, warpage of the cured film of the thermosetting resin composition is easily prevented.

When the thermosetting resin composition contains a surfactant such as an antifoaming agent or a leveling agent, workability during film formation and film properties before and after curing tend to be enhanced. The content ratio of the surfactant is in a range from 0.1% by mass to 5% by mass or in a range from 0.5% by mass to 3% by mass, relative to the mass of the resin A, for example.

### [Production Method]

The production method for the thermosetting resin composition is not particularly limited. A method can be applied in which the resin A, the trifunctional amine-type epoxy resin, the organic solvent, and an optional component such as an antifoaming agent, are mixed by means of a mixing method such as roll kneading and mixer mixing used for the production of ordinary paints, inks, and pastes, if necessary, for example. Each component can be added in order into a mixing container. Alternatively, a thermosetting resin composition set described below, may be used, and a first agent and a second agent may be added into the mixing container.

### <Thermosetting Resin Composition Set>

In one or more embodiments, the thermosetting resin composition set is used for obtaining the thermosetting resin composition, and contains a first agent containing a resin having an acid anhydride group or a carboxy group, and a second agent containing a trifunctional amine-type epoxy resin. By using the thermosetting resin composition set, each component can be stored stably. When the thermosetting resin composition set is used for obtaining the thermosetting resin composition further containing an optional epoxy resin, such as a tetrafunctional amine-type epoxy resin, the second agent may contain an optional epoxy resin. The first agent, the second agent, or both agents may contain an organic solvent and an optional component such as a filler or an antifoaming agent. The thermosetting resin composition set may be a set of two agents as the first agent and the second agent, or a set of three or more agents further having one or more agents containing at least one component selected from the resin A, another resin, a trifunctional amine-type epoxy resin, another epoxy resin, an organic solvent, a filler, and an antifoaming agent.

### <Cured Product of Thermosetting Resin Composition>

In one or more embodiments, the cured product can be obtained using the thermosetting resin composition according to the above embodiments, or the thermosetting resin composition set according to the above embodiments. Examples of the cured product include a cured film, a film, or a sheet. The cured product such as a cured film, a film, or a sheet may be a protective film. The cured product can be obtained by applying the thermosetting resin composition to a substrate to obtain a coating film, and then thermally curing the coating film, for example. The coating film may be dried before thermally curing. The cured product may be a protective film of a flexible printed board; or may be a protective film of a flexible printed board having a copper foil and a polyimide substrate in contact with the copper foil, for example.

Examples of the coating method include a spin coating method; a casting method; a dipping method; a dispensing method; and printing methods such as letterpress printing, intaglio printing, offset printing, lithographic printing, letterpress reverse offset printing, screen printing, and gravure printing. The heating temperature at the time of thermal curing is in a range from 60° C. to 200° C., in a range from 80° C. to 180° C., or in a range from 100° C. to 150° C., for example. The heating time is in a range from 10 minutes to 150 minutes, or in a range from 30 minutes to 120 minutes, for example.

### <Flexible Printed Board and Electronic Component>

In one or more embodiments, the flexible printed board may be a flexible printed wiring board. The flexible printed wiring board at least includes a substrate on which a wiring pattern is formed, a protective film covering at least a portion of the wiring pattern, and a plating layer covering at least a portion of the wiring pattern, for example. In one or more embodiments, the flexible printed board may be a flexible circuit board further having an electronic component such as a semiconductor device, in addition to the flexible printed wiring board. The flexible printed board has excellent detergent resistance due to a protective film thereof being the cured product according to the above embodiments.

Examples of the substrate include a polyimide film and a polyimide film with an epoxy adhesive layer. The thickness of the substrate is in a range from 10 μm to 200 μm, or in a range from 20 μm to 100 μm, for example.

The wiring pattern may be formed of a material containing copper. The wiring width of the wiring pattern is in a range from 5 μm to 200 μm, or in a range from 10 μm to 100 μm, for example. The plating layer may be formed of a material containing Sn, Ni, or Au.

The method for producing the flexible printed wiring board includes: preparing the substrate on which the wiring pattern is formed; printing the thermosetting resin composition according to the above embodiments so as to cover at least a portion of the wiring pattern; curing the printed thermosetting resin composition to form the protective film; and forming the plating layer so as to cover at least a portion of the wiring pattern, for example.

As a thermal curing condition, the temperature is in a range from 80° C. to 180° C., in a range from 90° C. to 160° C., or in a range from 120° C. to 150° C., from the viewpoint of preventing oxidation of wiring such as copper, and obtaining low warpage and flexibility suitable as a protective film, for example. The heating time is in a range from 30 minutes to 120 minutes, or in a range from 50 minutes to 90 minutes, from the viewpoint of preventing oxidation of wiring, and obtaining low warpage and flexibility suitable as a protective film, for example.

In one or more embodiments, the thermosetting resin composition according to the above embodiments is suitably used as an overcoat material for an electronic component, a liquid sealing material, or a material for forming an interlayer insulating film, a surface protective film, a solder resist layer, or an adhesion layer. Examples of the electronic component include, in addition to flexible printed boards such as Chip On Film (COF) and Tape Automated Bonding (Tab), semiconductor elements such as integrated circuits, transistors, and diodes, semiconductor devices including semiconductor elements and semiconductor packages, modules, rigid printed boards, and displays such as liquid crystal displays and organic EL displays.

Examples of the embodiments of the present invention will be described below. The present invention is not limited to the following embodiments.

(1) A thermosetting resin composition including: a resin having at least one group selected from the group consisting of an acid anhydride group and a carboxy group; and a trifunctional amine-type epoxy resin.
(2) The thermosetting resin composition according to (1) above, in which the trifunctional amine-type epoxy resin includes an epoxy resin represented by formula (E1) above.
(3) The thermosetting resin composition according to (1) or (2) above, in which a content ratio of the trifunctional amine-type epoxy resin is in a range from 1% by mass to 16% by mass, relative to a mass of the resin.
(4) The thermosetting resin composition according to any one of (1) to (3) above, further containing a tetrafunctional amine-type epoxy resin.
(5) The thermosetting resin composition according to (4) above, in which the tetrafunctional amine-type epoxy resin includes an epoxy resin represented by formula (E2) above.
(6) The thermosetting resin composition according to (4) or (5) above, in which a content ratio of the tetrafunctional amine-type epoxy resin is in a range from 1% by mass to 16% by mass, relative to the mass of the resin.
(7) The thermosetting resin composition according to any one of (1) to (6) above, further containing an epoxy resin other than the amine-type epoxy resins.
(8) The thermosetting resin composition according to any one of (1) to (7) above, in which a content ratio of a total of an epoxy resin is in a range from 4% by mass to 28% by mass, relative to the mass of the resin.
(9) The thermosetting resin composition according to any one of (1) to (8) above, in which the resin includes a polyamideimide having at least one group selected from the group consisting of an acid anhydride group and a carboxy group.
(10) The thermosetting resin composition according to any one of (1) to (9) above, in which the resin includes a polyamideimide having at least one group selected from the group consisting of an acid anhydride group and a carboxy group, and a urethane bond.
(11) The thermosetting resin composition according to (9) or (10) above, in which the polyamideimide has a structure derived from a polycarbonate diol represented by formula (P1) above.
(12) The thermosetting resin composition according to any one of (9) to (11) above, in which the polyamideimide has a structure represented by formula (P2) above.
(13) The thermosetting resin composition according to any one of (1) to (12), in which the thermosetting resin composition is for forming a protective film for a flexible printed board having a polyimide substrate and a copper foil in contact with the polyimide substrate.
(14) A thermosetting resin composition set for obtaining the thermosetting resin composition according to any one of (1) to (13), the thermosetting resin composition set including: a first agent containing the resin, and a second agent containing the trifunctional amine-type epoxy resin.
(15) A cured product obtained using the thermosetting resin composition according to any one of (1) to (13), or the thermosetting resin composition set according to (14).
(16) A film obtained using the thermosetting resin composition according to any one of (1) to (13), or the thermosetting resin composition set according to (14).
(17) A flexible printed board obtained using the thermosetting resin composition according to any one of (1) to (13), or the thermosetting resin composition set according to (14).
(18) An electronic component obtained using the thermosetting resin composition according to any one of (1) to (13), or the thermosetting resin composition set according to (14).

The disclosure of the present application is related to the subject matter described in Japanese Patent Application No. 2023-116179 filed on Jul. 14, 2023, the entire disclosed content of which is incorporated herein by reference.

### EXAMPLES

Embodiments of the present invention will be specifically described based on a series of examples. However, the embodiments of the present invention are not limited to the following examples.

### <Synthesis of Resin A>

The following were added to a reaction container equipped with a stirrer, a thermometer, and a condenser: 33.63 g (0.04 mol) of a polycarbonate diol (1) represented by formula (P1) above (R^{p} includes a structure derived from 1,4-cyclohexanedimethanol and a structure derived from 1,6-hexanediol in a molar ratio of 1:1, and an average value n is in a range from 4 to 6), 111.83 g (0.12 mol) of a polycarbonate diol (2) represented by formula (P1) above (R^{p} includes a structure derived from 1,4-cyclohexanedimethanol and a structure derived from 1,6-hexanediol in a molar ratio of 3:1, and an average value n is in a range from 4 to 6), and 76.74 g (0.04 mol) of a polycarbonate diol (3) represented by formula (P1) above (R^{p} includes a structure derived from 1,6-hexanediol, and an average value n is in a range from 21.5 to 23.5). Further, the following were added to the reaction container: 59.37 g (0.24 mol) of 4,4′-diphenylmethane diisocyanate, 27.56 g (0.16 mol) of a tolylene diisocyanate mixture (1) (mixture in which a mass ratio of 2,4-tolylene diisocyanate and 2,6-tolylene diisocyanate is 80:20), and 206.40 g of 7-butyrolactone, and they were stirred to obtain a mixture. The temperature of the mixture was raised to 150° C., all raw materials were dissolved, a reaction was performed for 4 hours, and then a polyisocyanate having a urethane bond was formed.

Next, the temperature of the obtained reaction solution was lowered to 70° C., and 55.76 g (0.29 mol) of trimellitic anhydride was added thereto and completely dissolved. Then, 13.86 g (0.06 mol) of 4,4′-diphenylmethane diisocyanate, 6.45 g (0.04 mol) of a tolylene diisocyanate mixture (1), and 170.51 g of 7-butyrolactone were added thereto, and they were stirred to obtain a mixture. The temperature of the mixture was raised to 120° C., all raw materials were dissolved, and a reaction was performed for 1 hour.

While adjusting the temperature of the obtained reaction solution, a reaction was performed at 160° C. for 5 hours, at 135° C. for 1 hour, and then at 120° C. for 1 hour. Next, 5.36 g (0.06 mol) of 2-butanone oxime and 142.27 g of 7-butyrolactone were added to finish the reaction. A polyamideimide-containing solution having a urethane bond (solid fraction amount: 40.5% by mass, hereinafter referred to as “varnish”) was obtained.

The polyamideimide had the number average molecular weight (Mn) of 6,900, the weight average molecular weight (Mw) of 46,500, the dispersion (Mw/Mn) of 6.72, and the acid value of 11 mgKOH/g.

GPC measurement conditions of the number average molecular weight and the weight average molecular weight of the polyamideimide, and a measurement method of the acid value of the polyamideimide are as follows.

### (Number Average Molecular Weight and Weight Average Molecular Weight)

Liquid feeding pump: “LC-20AD” manufactured by SHIMADZU CORPORATION
Autosampler: “SIL-20A HT” manufactured by SHIMADZU CORPORATION
Column oven: “CTO-20A” manufactured by SHIMADZU CORPORATION
UV detector: “SPD-M20A” manufactured by SHIMADZU CORPORATION
Column: Gelpack “GL-A160-S” and “GL-A150-S” manufactured by Hitachi High-Tech Corporation were connected in series.
Column size: inner diameter: 7.8 mm and length: 300 mm (GL-A160-S and GL-A150-S)
Eluent: tetrahydrofuran (THF)
Sample density: resin 10 mg/THE 2.5 mg
Injection volume: 20 μL
Flow rate: 1 mL/minute
Column temperature: 40° C.
Molecular weight standard substance: standard polystyrene (“PStQuick B, PStQuick C, and PStQuick D” manufactured by Tosoh Corporation)

### (Acid Value)

1 g of a polyamideimide was accurately weighed and put into a stoppered flask, 100 g of N-methylpyrrolidone was added thereto to dissolve the polyamideimide. Several drops of a thymol blue reagent were added to the obtained solution as an indicator, titration was performed with a 0.1 mol/L potassium hydroxide aqueous solution until a brown color was exhibited for 30 seconds, and an inflection point on a titration curve was determined as an end point. A “buret 25 mL” manufactured by AS ONE CORPORATION was used as a titrator.

The acid value was calculated based on the amount of the 0.1 mol/L potassium hydroxide aqueous solution required for the titration in accordance with the following formula.

$$Acid value = a \times F \times 5.611 / amount ( g ) of polyamideimide$$

$$a : Amount ( mL ) of 0.1 mol / L potassium hydroxide aqueous solution$$

$$F : Titer of 0.1 mol / L potassium hydroxide aqueous solution$$

### <Preparation of Thermosetting Resin Composition>

### Example 1

A polyamideimide varnish, an epoxy resin, an antifoaming agent, and a solvent were added to a rotation and revolution mixer (“AR-250” manufactured by THINKY CORPORATION). They were kneaded at a rotational speed of 2,000 rpm and a rotation time of 3 minutes to obtain a thermosetting resin composition. Table 1 shows the amount (parts by mass) of each component. The amount of polyamideimide in Table 1 is the solid fraction amount.

### Examples 1 to 10 and Comparative Examples 1 to 7

A thermosetting resin composition was obtained in the same manner as in Example 1 except that the epoxy resin and the like were changed to the components and amounts shown in Tables 1 and 2. The amount of polyamideimide in Tables 1 and 2 is the solid fraction amount.

TABLE 1

| | | Example | Example | Example | Example | Example | Example | Example | Example | Example | Example |
|---|---|---|---|---|---|---|---|---|---|---|---|
| Items | | 1 | 2 | 3 | 4 | 5 | 6 | 7 | 8 | 9 | 10 |
| Polyamideimide | | 100.0 | 100.0 | 100.0 | 100.0 | 100.0 | 100.0 | 100.0 | 100.0 | 100.0 | 100.0 |
| Epoxy resin | A | 5.6 | 1.6 | 1.6 | 1.6 | 9.4 | 3.3 | 3.3 | 13.1 | 4.6 | 15.1 |
| | B | | 3.3 | 3.3 | 3.3 | | 6.5 | 6.5 | | 9.2 | |
| | C | | | 7.4 | | | | | | | |
| | D | | | | | | | 17.9 | | | |
| | E | | | | | | | | | | |
| | F | | | | | | | | | | |
| | G | | | | 9.3 | | | | | | |
| Antifoaming agent | | 1.0 | 1.0 | 1.0 | 1.0 | 2.0 | 2.0 | 2.0 | 2.0 | 2.0 | 2.0 |
| Solvent | | 161.9 | 158.9 | 169.9 | 167.9 | 171.9 | 170.9 | 190.9 | 180.9 | 180.9 | 186.9 |
| Content rate of total of amine- | | 5.6 | 4.9 | 4.9 | 4.9 | 9.4 | 9.8 | 9.8 | 13.1 | 13.8 | 15.1 |
| type epoxy resin (% by mass) | | | | | | | | | | | |
| Content rate of total of | | 5.6 | 4.9 | 12.3 | 14.2 | 9.4 | 9.8 | 27.7 | 13.1 | 15.1 | 13.8 |
| epoxy resin (% by mass) | | | | | | | | | | | |
| Evaluation | Detergent | 99 | 47 | 78 | 125 | 358 | 159 | 353 | 45 | 42 | 65 |
| results | resistance (h) | | | | | | | | | | |
| | Low | 5.0 | 6.2 | 4.4 | 5.9 | 3.7 | 4.3 | 3.6 | 2.8 | 2.6 | 3.6 |
| | warpage (mm) | | | | | | | | | | |

TABLE 2

| | | Comparative | Comparative | Comparative | Comparative | Comparative | Comparative | Comparative |
|---|---|---|---|---|---|---|---|---|
| Items | | Example 1 | Example 2 | Example 3 | Example 4 | Example 5 | Example 6 | Example 7 |
| Polyamideimide | | 100.0 | 100.0 | 100.0 | 100.0 | 100.0 | 100.0 | 100.0 |
| Epoxy resin | A | | | | | | | |
| | B | 5.5 | | | | | | |
| | C | | 7.4 | | | | | |
| | D | | | 9.0 | 17.9 | | | |
| | E | | | | | 11.2 | | |
| | F | | | | | | 16.1 | |
| | G | | | | | | | 18.6 |
| Antifoaming agent | | 1.0 | 1.0 | 1.0 | 2.0 | 2.0 | 2.0 | 2.0 |
| Solvent | | 160.9 | 156.9 | 154.9 | 162.9 | 176.9 | 164.9 | 161.9 |
| Content rate of total of amine- | | 5.5 | 0.0 | 0.0 | 0.0 | 0.0 | 0.0 | 0.0 |
| type epoxy resin (% by mass) | | | | | | | | |
| Content rate of total of | | 5.5 | 7.4 | 9.0 | 17.9 | 11.2 | 16.1 | 18.6 |
| epoxy resin (% by mass) | | | | | | | | |
| Evaluation | Detergent | 10 | 9 | 8 | 8 | 16 | 6 | 10 |
| results | resistance (h) | | | | | | | |
| | Low warpage (mm) | 6.1 | 5.3 | 6.7 | 6.1 | 4.7 | 5.7 | 5.0 |

Components used in examples and comparative examples are described below.

### Polyamideimide: Polyamideimide Obtained in a Synthesis Example

### Epoxy Resins

A: Trifunctional amine-modified epoxy resin (N,N-bis(2,3-epoxypropyl)-4-(2,3-epoxypropoxy)aniline, epoxy equivalent 95 g/eq, EP-3950S/manufactured by ADEKA CORPORATION)
B: Tetrafunctional amine-modified epoxy resin (N,N,N′,N′-tetraglycidyl-4,4′-diaminodiphenylmethane, epoxy equivalent 117 g/eq, YH-434L/manufactured by NIPPON STEEL Chemical & Material Co., Ltd.)
C: Polyfunctional butadiene epoxy resin (epoxy equivalent: 165 g/eq, PB4700/manufactured by Daicel Corporation)
D: Tetrafunctional siloxane epoxy resin (epoxy equivalent: 200 g/eq, KR470/manufactured by Shin-Etsu Chemical Co., Ltd.)
E: Tetrafunctional bisphenol A type epoxy resin (epoxy equivalent: 124 g/eq, BATG/manufactured by Resonac Corporation)
F: Polyfunctional cyclohexane epoxy resin (epoxy equivalent: 180 g/eq, EHPE3150/manufactured by Daicel Corporation)
G: Polyfunctional bisphenol A type epoxy resin (epoxy equivalent: 207 g/eq, jER157S70/Manufactured by Mitsubishi Chemical Corporation)
Antifoaming agent: acrylic antifoaming agent (DISPARLON LF-1983, manufactured by Kusumoto Chemicals, Ltd.)
Solvent: γ-butyrolactone

### <Evaluation>

A flexible copper-clad laminate was produced using a thermosetting resin composition by means of the following method, and detergent resistance and low warpage thereof were evaluated. Tables 1 and 2 show evaluation results.

### [Detergent Resistance]

### (Production of Flexible Copper-Clad Laminate)

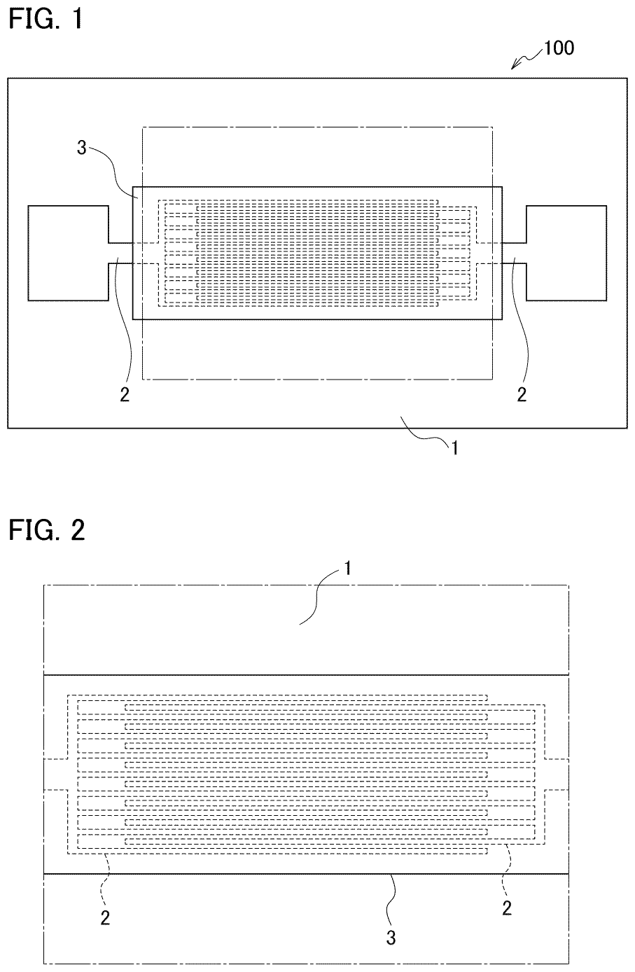

A flexible copper-clad laminate (length: 20 mm, width: 27 mm) was prepared, which included a polyimide film (thickness: 38 μm), and comb-shaped copper wiring (wiring pattern, copper wiring section width/copper wiring section-copper wiring section width=10.0 μm/10.0 μm, number of copper wiring: 17) having a copper foil (sputtered copper, thickness: 8 μm), and an Sn plating layer (thickness: 0.2 μm to 0.3 μm) formed on the copper foil. A thermosetting resin composition was applied to the laminate by means of screen printing under the following conditions (length 4 mm, width 17 mm, dry film thickness 10 μm). The applied thermosetting resin composition was cured by heating at 80° C. for 3 minutes and then at 140° C. for 30 minutes to form a protective film. The laminate to which the protective film was formed, was used as a test piece. FIGS. 1 and 2 are schematic diagrams of the test piece. FIG. 2 is an enlarged view of a portion within a dashed line region in FIG. 1. In FIGS. 1 and 2, reference numeral 1 denotes a polyimide film, reference numeral 2 denotes a wiring pattern, reference numeral 3 denotes a protective film, and reference numeral 100 denotes a test piece.

### (Printing Conditions)

Printing machine: “LS-34GX” manufactured by NEWLONG SEIMITSU KOGYO CO., LTD.
Mesh plate: “3D250 mesh plate” manufactured by MURAKAMI CO., LTD.
Printing speed: 80 mm/sec

### (Evaluation of Detergent Resistance)

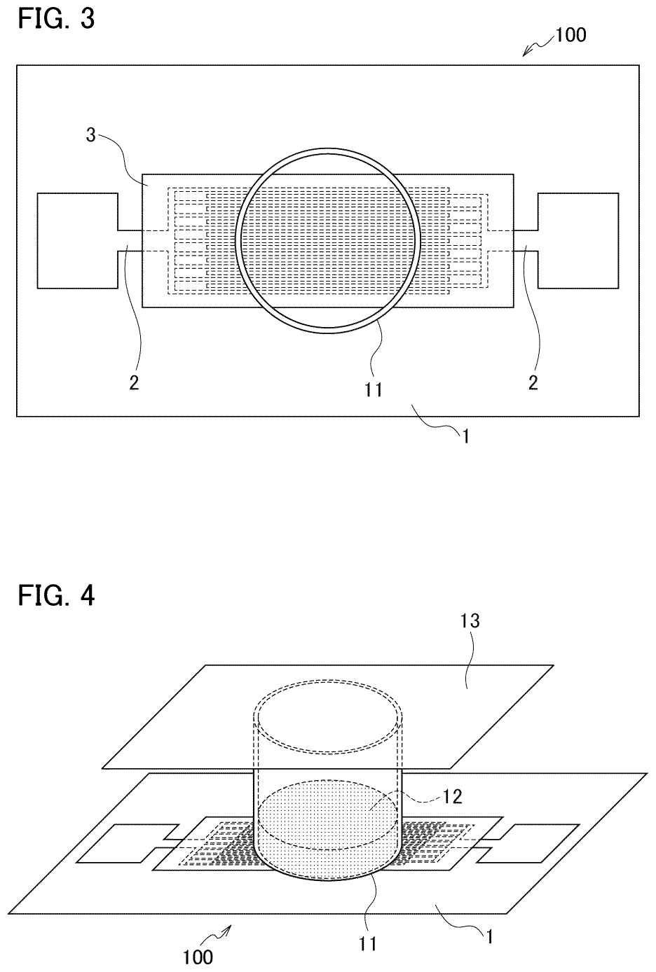

Hollow cylindrical plastic (inner diameter: 7 mm) was attached to the test piece using a silicone adhesive (“Cemedine Super X2” manufactured by CEMEDINE CO., LTD.), such that one end of a side surface of the cylinder was in contact with a surface on the protective film side. A glass cleaner (“WindexSC” manufactured by Johnson, containing water, alcohol, alkanolamine, surfactant, and the like) was added to the inside of the hollow cylindrical plastic, and a cover film (PET film) was attached to the other end of the side surface of the cylinder using a silicone adhesive. FIGS. 3 and 4 are schematic diagrams of the test piece in contact with the glass cleaner. FIG. 3 is a plan view, and FIG. 4 is a perspective view. In FIGS. 3 and 4, reference numeral 1 denotes the polyimide film, reference numeral 2 denotes the wiring pattern, reference numeral 3 denotes the protective film, reference numeral 11 denotes a hollow cylindrical plastic, reference numeral 12 denotes a glass cleaner, reference numeral 13 denotes a cover film, and reference numeral 100 denotes the test piece.

A voltage of 20 V was applied to the test piece in an atmosphere having a temperature of 23° C. and a relative humidity of 60%, and a time (h) from the start of application to the occurrence of a short circuit between wiring sections was measured. A time when a resistance value became less than 1.0×10⁶Ω was regarded as a time when a short circuit occurred between wiring sections.

### [Low Warpage]

### (Production of Flexible Copper-Clad Laminate)

A flexible copper-clad laminate (length: 48 mm, width: 35 mm) was prepared, which included a polyimide film (thickness: 38 μm), and copper wiring (wiring pattern) having a copper foil (sputtered copper, thickness: 8 μm), and an Sn plating layer (thickness: 0.2 μm to 0.3 μm) formed on the copper foil. A thermosetting resin composition was applied to the laminate by means of screen printing under the following conditions (length: 48 mm, width: 35 mm, dry film thickness: 10 μm). The applied thermosetting resin composition was cured by heating at 80° C. for 3 minutes and then at 140° C. for 30 minutes, to form a protective film. The laminate to which the protective film was formed, was used as a test piece.

### (Printing Conditions)

Printing machine: “LS-34GX” manufactured by NEWLONG SEIMITSU KOGYO CO., LTD.
Mesh plate: “SUS200 mesh plate” manufactured by MURAKAMI CO., LTD.
Printing speed: 80 mm/sec
   (Evaluation of low warpage)

After curing, the test piece was placed in a stationary position at room temperature (25° C.) for 24 hours. The test piece was placed on a surface plate, while a protective film surface faced down. A distance (mm) from the surface plate to the top of the warpage of the flexible copper-clad laminate was measured.

### REFERENCE SIGNS LIST

1 Polyimide film
2 Wiring pattern
3 Protective film
11 Hollow cylindrical plastic
12 Glass cleaner
13 Cover film
100 Test piece

1. A thermosetting resin composition comprising:
a resin having at least one group selected from the group consisting of an acid anhydride group and a carboxy group; and
a trifunctional amine-type epoxy resin.

2. The thermosetting resin composition according to claim 1, wherein
the trifunctional amine-type epoxy resin includes an epoxy resin represented by formula (E1) below: 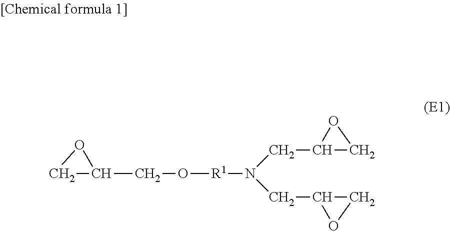
wherein, R¹ represents a divalent organic group.

3. The thermosetting resin composition according to claim 1, wherein
a content ratio of the trifunctional amine-type epoxy resin is in a range from 1% by mass to 16% by mass, relative to a mass of the resin.

4. The thermosetting resin composition according to claim 1, further containing a tetrafunctional amine-type epoxy resin.

5. The thermosetting resin composition according to claim 4, wherein
the tetrafunctional amine-type epoxy resin includes an epoxy resin represented by formula (E2) below: 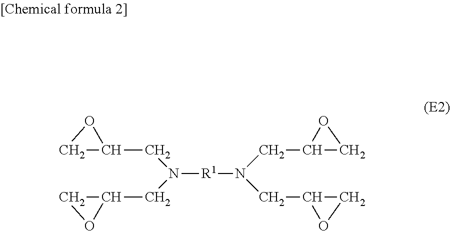
wherein, R² represents a divalent organic group.

6. The thermosetting resin composition according to claim 4, wherein
a content ratio of the tetrafunctional amine-type epoxy resin is in a range from 1% by mass to 16% by mass, relative to the mass of the resin.

7. The thermosetting resin composition according to claim 1, further containing an epoxy resin other than the amine-type epoxy resin.

8. The thermosetting resin composition according to claim 1, wherein
a content ratio of a total of an epoxy resin is in a range from 4% by mass to 28% by mass, relative to the mass of the resin.

9. The thermosetting resin composition according to claim 1, wherein
the resin includes a polyamideimide having at least one group selected from the group consisting of an acid anhydride group and a carboxy group.

10. The thermosetting resin composition according to claim 1, wherein
the resin includes a polyamideimide having at least one group selected from the group consisting of an acid anhydride group and a carboxy group, and a urethane bond.

11. The thermosetting resin composition according to claim 9, wherein
the polyamideimide has a structure derived from a polycarbonate diol represented by formula (P1) below: 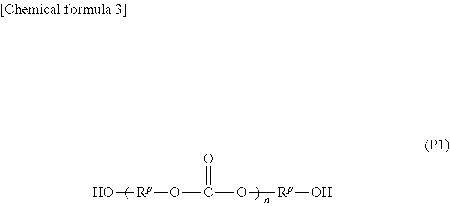
wherein, R^{p}s represent a divalent organic group having an alicyclic hydrocarbon group of 5 to 10 carbon atoms, or a divalent organic group having an aliphatic hydrocarbon group of 1 to 18 carbon atoms, the divalent organic group does not have an alicyclic hydrocarbon group, and n represents a number from 1 to 30. R^{p}s may be the same or different from each other.

12. The thermosetting resin composition according to claim 9, wherein
the polyamideimide has a structure represented by formula (P2) below: 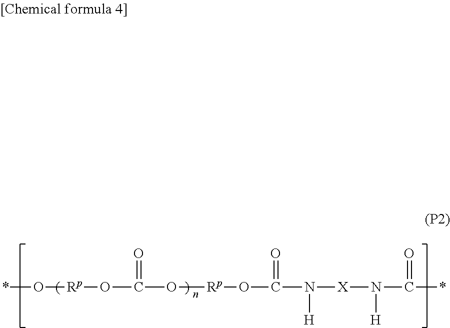
wherein, R^{p}s represent a divalent organic group having an alicyclic hydrocarbon group of 5 to 10 carbon atoms, or a divalent organic group having an aliphatic hydrocarbon group of 1 to 18 carbon atoms, the divalent organic group does not have an alicyclic hydrocarbon group, X represents a divalent organic group, and n represents a number from 1 to 30. R^{p}s may be the same or different from each other. A symbol * represents a bonding site to another structure.

13. The thermosetting resin composition according to claim 1, wherein
the thermosetting resin composition is for forming a protective film for a flexible printed board having a polyimide substrate and a copper foil in contact with the polyimide substrate.

14. A thermosetting resin composition set for obtaining the thermosetting resin composition according to claim 1, the thermosetting resin composition set comprising:
a first agent containing the resin; and
a second agent containing the trifunctional amine-type epoxy resin.

15. A cured product obtained using the thermosetting resin composition according to claim 1.

16. A film obtained using the thermosetting resin composition according to claim 1.

17. A flexible printed board obtained using the thermosetting resin composition according to claim 1.

18. An electronic component obtained using the thermosetting resin composition according to claim 1.
